(19) United States
(12) Patent Application Publication
(10) Pub. No.: US 2007/0262371 A1
(43) Pub. Date: Nov. 15, 2007

(54) Semiconductor device and manufacturing method thereof

(76) Inventor: Hisataka Meguro, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/797,995

(22) Filed: May 9, 2007

(30) Foreign Application Priority Data
May 10, 2006 (JP) 2006-131799

(51) Int. Cl. H01L 29/788

(52) U.S. Cl. 257/315

(57) ABSTRACT

A semiconductor device includes first and second memory cells lying adjacently each other, the first cell comprising first island region and first conductive spacer, the first region including first island semiconductor portion, first insulating film and first FG, the first spacer provided on upper side portion of first FG, the second cell comprising second island region and-second conductive spacer, the second region including second island semiconductor portion adjacent to the first portion, second insulating film and second FG, the second spacer provided on upper side portion of second FG, the cells comprising interelectrode insulating film (IPD) and the CG, edge of under portion of the IPD positioned lower than bottom surfaces of the FGs, edge of under portion of the CG positioned equal to the bottom surfaces of the FGs or lower, the IPD being failed to have bending portion between side surface of FGs and CG.

### CROSS-REFERENCE TO RELATED APPLICATIONS

This application is based upon and claims the benefit of priority from prior Japanese Patent Application No. 2006-131799, filed May 10, 2006, the entire contents of which are incorporated herein by reference.

### BACKGROUND OF THE INVENTION

1. Field of the Invention

This invention relates to a semiconductor device and a manufacturing method thereof and more particularly to a semiconductor device comprising memory cells including floating gate electrodes and control gate electrodes and a manufacturing method thereof.

2. Description of the Related Art

A nonvolatile semiconductor memory is exemplified as one of semiconductor memory devices. In recent years, there has been a growing demand for the nonvolatile semiconductor memory used as a data storage device. A NAND type flash memory is known as a typical electrically-rewritable nonvolatile semiconductor memory using floating gate electrodes (Jpn. Pat. Appln. KOKAI Publication No. 2002-359308).

In FIG. 17, a cross sectional view showing a conventional NAND type flash memory is shown. FIG. 17 is a cross sectional view taken along the channel width direction. In FIG. 17, 300 indicates a silicon substrate, 301 indicates a tunnel insulating films, 302 indicates a floating gate electrode, 303 indicates an isolation insulating films, 304 indicates a gate interelectrode insulating film and 305 indicates a control gate electrode.

The device structure shown in FIG. 17 is formed according to the following manufacturing process.

First, an insulating film, a polycrystalline silicon film are formed on the silicon substrate 300.

Next, the polycrystalline silicon film, the insulating film and the silicon substrate 300 are etched by RIE (Reactive Ion Etching) process using a hard mask. As a result, the floating gate electrodes 302 and the tunnel insulating films 301 shown in FIG. 17 are formed, and further trenches for isolation are formed on a surface of the silicon substrate 300.

Next, the trenches are filled with the isolation insulating films 303 by deposition and planarization of an insulation film. Thereafter, the gate interelectrode insulating film 304 and control gate electrode 305 are formed to complete the device structure shown in FIG. 17.

However, the device structure thus obtained by the above manufacturing process has the following problem. As shown in FIG. 17, sharp corner portions are formed on the upper portions of the floating gate electrodes 302. Therefore, concentration of an electric field occurs in portions between the sharp corner portions of the floating gate electrodes 302 and the control gate 305. The concentration of the electric filed increases a leak current in the gate interelectrode insulating film 304 at the time of data write/erase operation.

A coupling capacitance exists between the adjacent floating gate electrodes 302. Due to this coupling capacitance, interference (adjacent inter-cell interference) occurs between the adjacent memory cells. The adjacent interl-cell interference causes a variation in an electric potential of the floating gate electrode 302 and this electric potential variation causes a variation in the threshold voltage. The distance between the adjacent floating gate electrodes 302 is further reduced with miniaturization of the device element. Therefore, it is considered that the influence by the adjacent interl-cell interference becomes greater in the future.

### BRIEF SUMMARY OF THE INVENTION

According to an aspect of the present invention, there is provided a semiconductor device comprising: a semiconductor substrate; a trench type isolation region provided on a surface of the semiconductor substrate; and an electrically-rewritable nonvolatile semiconductor memory cell array including first and second memory cells isolated each other by the trench type isolation region and lying adjacently each other; the first memory cell comprising a first island shaped region and a first conductive spacer, the first island shaped region including a first island shaped semiconductor portion provided on the semiconductor substrate, a first insulating film provided on the first semiconductor portion and a first floating gate electrode provided on the first insulating film, the first conductive spacer being selectively provided on a side surface of an upper portion of the first floating gate electrode, the second memory cell comprising a second island shaped region and a second conductive spacer, the second island shaped region including a second island shaped semiconductor portion being adjacent to the first island shaped semiconductor portion and provided on the semiconductor substrate which is separated from the first island shaped semiconductor portion by the trench type isolation region, a second insulating film provided on the second island shaped semiconductor portion, and a second floating gate electrode provided on the second insulating film, the second conductive spacer being selectively provided on a side surface of an upper portion of the second floating gate electrode, the first and second memory cells further comprising an interelectrode insulating film, and a control gate electrode provided on the interelectrode insulating film, the interelectrode insulating film being provided on the first island shaped region, the first conductive spacer, the second island shaped region, the second conductive spacer and an region between the first island shaped region and the second island shaped region, and a front edge of an under portion of the interelectrode insulating film being positioned lower than bottom surfaces of the first and second floating gate electrodes, a front edge of an under portion of the control gate electrode being positioned equal to the bottom surfaces of the first and second floating gate electrodes or lower, the interelectrode insulating film being failed to have a bending portion between a side surface of the first floating gate electrode and the control gate electrode, and between a side surface of the second floating gate electrode and the control gate electrode.

According to an aspect of the present invention, there is provided a method for manufacturing a semiconductor device comprising: a semiconductor substrate, a trench type isolation region provided on a surface of the semiconductor substrate, an electrically-rewritable nonvolatile semiconductor memory cell array including first and second memory cells isolated each other by the trench type isolation region and lying adjacently each other, the method comprising: forming the first memory cell; forming the second memory cell; the forming the first and second memory cells comprising: forming an insulating film to be processed into the first and second insulating films, forming a conductive film to be processed into the first and second floating gate electrode, forming the first and second floating gate electrodes, forming the first and second insulating films respectively under the first and second floating gate electrodes, and forming first and second island shaped semiconductor portions respectively under the first and second insulating films by etching the conductive film, the insulating film, the semiconductor substrate, filling a region between a first island shaped region and a second island shaped region with an insulating member, the first island shaped region including the first island shaped semiconductor portion, the first insulating film and the first floating gate electrode, the second island shaped region including the second island shaped semiconductor portion, the second insulating film and the second floating gate electrode, and a top surface of the insulating member being lower than top surfaces of the first and second of the floating gate electrodes and higher than bottom surfaces of the first and second of the floating gate electrodes forming first and second conductive spacers respectively on side surfaces of the first and second floating gate electrodes which are not covered with the insulating member, forming a concave portion on a surface of the insulating member by etching the insulating member using the first and second conductive spacers as a mask, a bottom of the concave portion being lower than the bottom surfaces of the first and second floating gate electrodes, forming an interelectrode insulating film and a control gate electrode, the interelectrode insulating film being formed on the first island shaped region, the first conductive spacer, the second island shaped region, the second conductive spacer and an region between the first island shaped region and the second island shaped region, the control gate electrode being formed on the interelectrode insulating film, a front edge of the under portion of interelectrode insulating film and a front edge of the under portion of the control gate electrode being in the concave portion of the insulating member, the front edge of the under portion of the interelectrode insulating film being positioned lower than bottom surfaces of the first and second floating gate electrodes, the front edge of the under portion of the control gate electrode being positioned equal to the bottom surfaces of the first and second floating gate electrodes or lower, the interelectrode insulating film being failed to have a bending portion between a side surface of the first floating gate electrode and the control gate electrode, and between a side surface of the second floating gate electrode and the control gate electrode.

### BRIEF DESCRIPTION OF THE SEVERAL VIEWS OF THE DRAWING

FIG. 1 is a plane view of memory cells of a NAND type flash memory;

FIG. 2 is an equivalent circuit diagram of the memory cells of FIG. 1;

FIG. 3 is a cross sectional view illustrating the memory cells in a channel width direction (word line direction);

FIG. 4 is a cross sectional views illustrating a manufacturing process of memory cells of the NAND type flash memory of an embodiment;

FIG. 5 is a cross-section view illustrating the manufacturing process of the memory cells of the NAND type flash memory of the embodiment following FIG. 4;

FIG. 6 is a cross-section view illustrating the manufacturing process of the memory cells of the NAND type flash memory of the embodiment following FIG. 5;

FIG. 7 is a cross-section view illustrating the manufacturing process of the memory cells of the NAND type flash memory of the embodiment following FIG. 6;

FIG. 8 is a cross-section view illustrating the manufacturing process of the memory cells of the NAND type flash memory of the embodiment following FIG. 7;

FIG. 9 is a cross-section view illustrating the manufacturing process of the memory cells of the NAND type flash memory of the embodiment following FIG. 8;

FIG. 10 is a cross-section view illustrating the manufacturing process of the memory cells of the NAND type flash memory of the embodiment following FIG. 9;

FIG. 11 is a cross-section view illustrating the manufacturing process of the memory cells of the NAND type flash memory of the embodiment following FIG. 10;

FIG. 12 is a cross-section view illustrating the manufacturing process of the memory cells of the NAND type flash memory of the embodiment following FIG. 11;

FIG. 13 is a cross-section view illustrating a gate interelectrode insulating film which is thinned on a boundary portion between a floating gate electrode and an isolation insulating film;

FIG. 14 is a schematic view illustrating a device comprising the NAND type flash memory of the embodiment;

FIG. 15 is a schematic view illustrating another device comprising the NAND type flash memory of the embodiment;

FIG. 16 is a schematic view illustrating yet another device comprising the NAND type flash memory of the embodiment; and

FIG. 17 is a cross-section view illustrating a conventional NAND type flash memory.

### DETAILED DESCRIPTION OF THE INVENTION

There will now be described an embodiment of present invention with reference to the accompanying drawings.

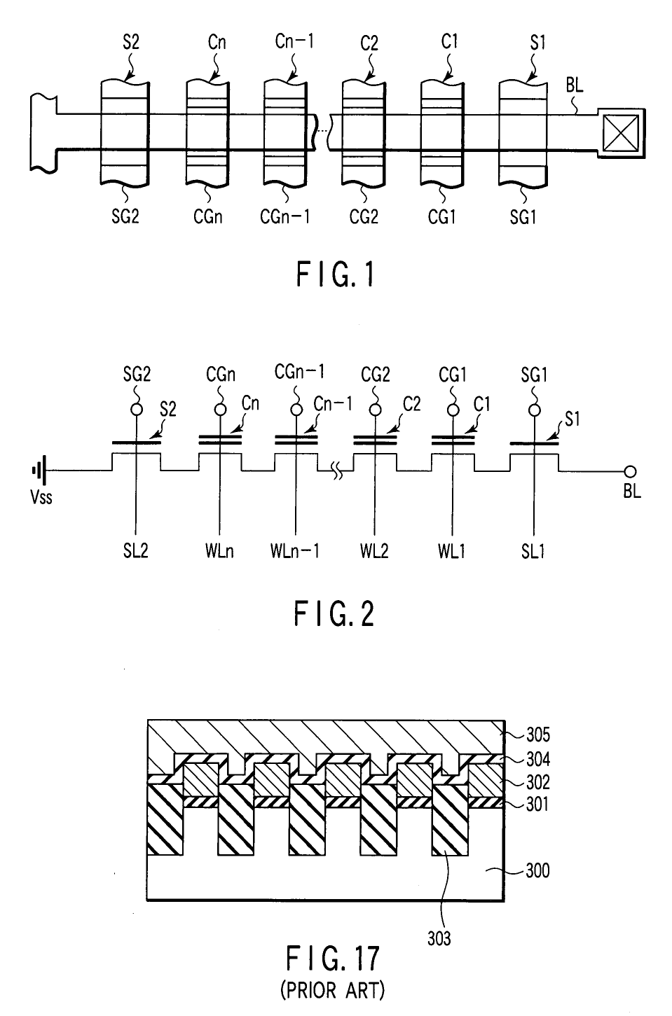

FIG. 1 is a plane view of memory cells of a NAND type flash memory and FIG. 2 is an equivalent circuit diagram of the memory cells.

In FIGS. 1 and 2, C1, C2, . . . , Cn indicate memory cells, S1 and S2 indicate selection transistors, CG1 (WL1), CG2 (WL2), . . . , CGn (WLn) indicate floating gate electrodes (word lines), SG1 and SG2 indicate selection gate electrodes, BL indicates a bit line, and Vss indicates power supply voltage (ground). Although not shown in FIGS. 1 and 2, a plurality of memory cells are arranged in the channel width direction (word line direction) of the memory cells. Thus, in practice, a plurality of bit lines and a plurality of word lines intersect with one another and memory cells are arranged in the intersecting positions.

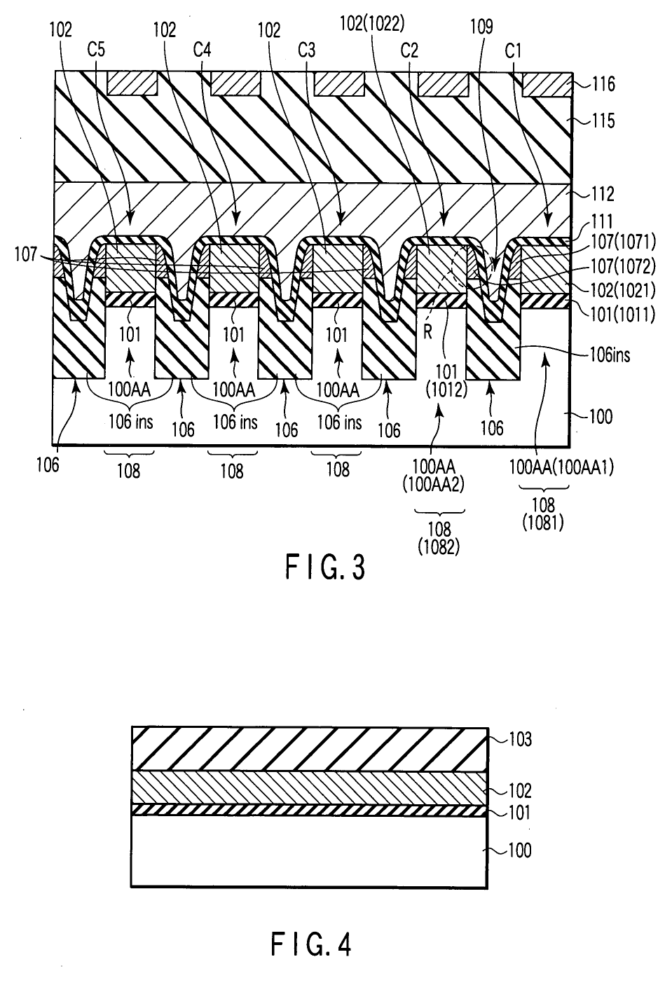

FIG. 3 is a cross sectional view showing the memory cells in the channel width direction (word line direction).

The NAND type flash memory of the present embodiment comprises a silicon substrate 100, a trench type isolation region 106 provided on a surface of the silicon substrate 100, and an electrically rewritable semiconductor memory cell array provided on the silicon substrate 100 and including first to fifth memory cells C1 to C5 which are isolated from one another by the isolation region 106. Here, for simplicity, only the five memory cells C1 to C5 are shown, but in practice, more of memory cells are provided.

In FIG. 3, 100 AA (100AA1, 100AA2) indicates an island shaped silicon portions (island shaped active regions), 101 (101₁, 101₂) indicates a tunnel insulating film, 102 (102₁, 102₂) indicates a floating gate electrode, 106ᵢₙₛ indicates insulating a member for isolation, 107 (107₁, 107₂) indicates a conductive spacer, 108 (108₁, 108₂) indicates an island shaped region, 109 indicates a concave portion (slit), 111 indicates a gate interelectrode insulating film, 112 indicates a control gate electrode, 115 indicates an inter-level insulating film and 116 indicates a bit line.

A case wherein the first and second memory cells C1, C2 are used as two adjacent memory cells, for example, is explained below, but the same explanation can be applied to other adjacent two memory cells.

The first memory cell C1 comprises a first island shaped region 108₁ which includes a first island shaped silicon portion 100AA1, a first tunnel insulating film 101₁ provided on the first island shaped silicon portion 100AA1 and a first floating gate electrode 102₁ provided on the first island shaped region 101₁. Further, the first memory cell C1 comprises first conductive spacers 107₁ which are selectively provided on the upper side surfaces of the first floating gate electrode 102₁. In the present embodiment, the first floating gate electrode 102₁ and first conductive spacers 107₁ contain the same material (Si).

The second memory cell C2 comprises a second island shaped region 108₂ which includes a second island shaped silicon portion 100AA2 provided adjacent to the first island shaped silicon portion 100AA1 and isolated from the first island shaped silicon portion 100AA1 by the isolation region 106, a second tunnel insulating film 101₂ provided on the second island shaped silicon portion 100AA2 and a second floating gate electrode 102₂ provided on the second island shaped region 101₂. Further, the second memory cell C1 comprises second conductive spacers 107₂ which are selectively provided on the upper side surfaces of the second floating gate electrode 102₂.

The first and second memory cells C1, C2 comprises a common gate interelectrode insulating film 111 and a common control gate electrode 112 provided on the gate interelectrode insulating film 111.

The gate interelectrode insulating film 111 is provided on the first island shaped region 108₁, first conductive spacers 107₁, second island shaped region 108₂, second conductive spacers 107₂ and a region between the first island shaped region 108₁ and the second island shaped region 108₂.

A front edge of an under portion of the gate interelectrode insulating film 111 is positioned lower than the bottom surfaces of the first and second tunnel insulating films 101₁, 101₂. A front edge of an under portion of the control gate electrode 112 is positioned lower than the bottom surfaces of the first and second floating gate electrodes 102₁, 102₂.

It is sufficient if the front edge of the under portion of the gate interelectrode insulating film 111 is positioned lower than the bottom surfaces of the first and second floating gate electrodes 102₁, 102₂. Further, it is permissible if the front edge of the under portion of the control gate electrode 112 is positioned at the same height as the bottom surfaces of the first and second floating gate electrodes 102₁, 102₂. The front edge of the under portion of the gate interelectrode insulating film 111 does not reach the surface of the silicon substrate 100.

Thus, since the front edge of the under portion of the control gate electrode 112 is positioned at the same height as or lower than the bottom surfaces of the first and second floating gate electrodes 102₁, 102₂, the first and second floating gate electrodes 102₁, 102₂ are electrostatically shielded from each other by the control gate electrode 112. Therefore, a variation in the electric potentials (a variation in the threshold voltages) of the first and second floating gate electrodes 102₁, 102₂ due to the coupling capacitance between the first and second floating gate electrodes 102₁ and 102₂ is suppressed.

The isolation region 106 comprises the insulating member 106ins having a concave portion on its surface and the insulating member 106ins is provided between the first island shaped region 108₁ and the second island shaped region 108₂. The bottom of the concave portion of the insulating member 106ins is positioned lower than the bottom surfaces of the first and second floating gate electrodes 102₁, 102₂ and further positioned lower than the bottom surfaces of the first and second tunnel insulating films 101₁, 101₂. The front edge of the under portion of the gate interelectrode insulating film 111 and the front edge of the under portion of the control gate electrode 112 are provided in the concave portion. Therefore, the front edge of the under portion of the control gate electrode 112 is positioned lower than the bottom surfaces of the first and second floating gate electrodes 102₁, 102₂ as described above.

The dimensions of the first and second conductive spacers 107₁, 107₂ in the lateral direction become gradually larger in a direction from the top surfaces to the bottom surfaces of the first and second floating gate electrodes 102₁, 102₂. The reason why the first and second conductive spacers 107₁, 107₂ includes such a shape is that the first and second conductive spacers 107₁, 107₂ are formed by deposition of a conductive film and anisotropic dry etching of the conductive film.

The concave portion of the insulating member 106ins includes side surfaces having a forwardly tapered shape (tapered so that the width thereof becomes narrower in the downward direction). The bottom of the concave portion of the insulating member 106ins lies in the central region between the first and second conductive spacers 107₁ and 107₂ as viewed from above. The upper side surfaces of the concave portion of the insulating member 106ins are substantially continuously connected to the bottom surfaces of the first and second conductive spacers 107₁, 107₂. The reason why the concave portion of the insulating member 106ins has such a shape and a position is that the concave portion of the insulating member 106ins is formed in a self-alignment manner by dry etching using the first and second conductive spacers 107₁, 107₂ as a mask.

Moreover, the surface of the insulating member 106ins lying under the bottom surface of the conductive spacer 107 (107₁, 107₂) is flat (parallel to the substrate surface).

No bent portion is formed in the gate interelectrode insulating film 111 of a region R between the side surface of the floating gate electrode 102 (102₁, 102₂) and the control gate electrode 112 and the gate interelectrode insulating film 111 of the region R has a parallel plate form. Thereby, the structure in which no electric field concentration occurs with respect to bidirectional electric field stress can be realized and deterioration in the dielectric strength of the gate interelectrode insulating film 111 can be suppressed.

FIGS. 4 to 12 are cross sectional views showing a manufacturing process of memory cells of the NAND type flash memory of the present embodiment.

[FIG. 4]

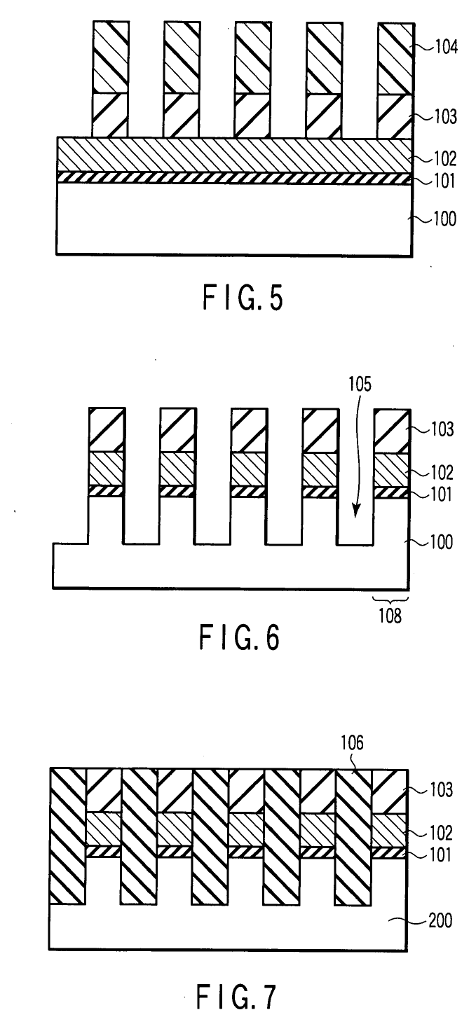

A tunnel insulating film 101 is formed on a silicon substrate 100. For example, the thickness of the tunnel insulating film 101 is 8 nm. A polycrystalline silicon film 102 having a conductive property to be processed into the first floating gate electrodes is formed on the tunnel insulating film 101. For example, the polycrystalline silicon film 102 having the conductive property is a polycrystalline silicon film having phosphorus (P) doped therein. For example, the thickness of the polycrystalline silicon film 102 is 60 nm. An amorphous silicon film having dopant (P) doped therein can be used instead of the polycrystalline silicon film 102 having dopant (P) doped therein. A silicon nitride film 103 to be processed into a hard mask is formed on the polycrystalline silicon film 102. For example, the thickness of the silicon nitride film 103 is 100 nm.

[FIG. 5]

A resist pattern 104 is formed on the silicon nitride film 103. The silicon nitride film 103 is etched by RIE (Reactive Ion Etching) process using the resist pattern 104 as a mask. As a result, the pattern of the resist pattern 104 is transferred onto the silicon nitride film 103. The silicon nitride film 103 is hereinafter referred to as a hard mask 103. An anisotropic dry etching process other than the RIE process maybe be used.

[FIG. 6]

The resist pattern 104 is removed by dry etching and wet etching. The polycrystalline silicon film 102 and tunnel insulating film 101 are etched by RIE process using the hard mask 103 as a mask, and further, the silicon substrate 100 is etched to desired depth.

As a result, island shaped silicon portions 100AA are formed on the silicon semiconductor substrate 100. Further, island shaped regions 108 each including the island shaped silicon portion 100AA, a tunnel insulating film 101 provided on the island shaped silicon portion 100AA and a floating gate electrode 102 provided on the tunnel insulating film 101 are formed. At this stage, the shape of the first floating gate electrode 102 in the channel width direction is determined. Further, a trench 105 for STI (Shallow Trench Isolation) is formed on the surface region of the silicon substrate. The anisotropic dry etching process other than the RIE process can be used. In order to recover from the damages caused by the above etching process on the etching surfaces (side surfaces) of the tunnel insulating films 101 and the etching surfaces (side surfaces and bottom surfaces of the trenches 105) of the silicon substrate 100, a post-oxidation film (not shown) is formed.

[FIG. 7]

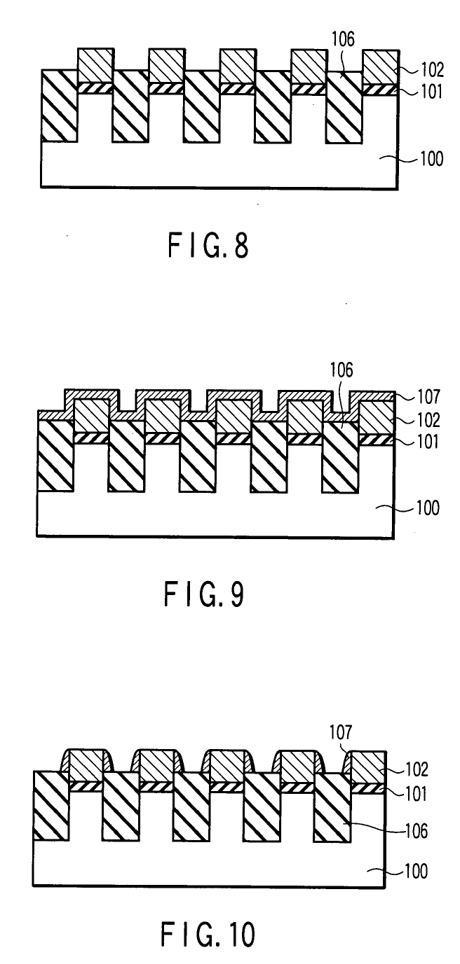

In order to fill the trench portions between the adjacent floating gate electrodes 102, an isolation insulating film 106 is deposited on the entire surface. The thickness of the isolation insulating film 106 is 600 nm, for example. Next, in order to make the surface planarized, the isolation insulating film 106 is polished by CMP (Chemical Mechanical Polishing) process.

[FIG. 8]

The hard mask (silicon nitride film) 103 is selectively removed by wet process. For example, the wet process is a wet etching using H₃PO₄ (hot phosphoric acid). Next, in order to lower the height of the isolation insulating film 106 to a desired position, the isolation insulating film 106 is polished by CMP process. With the above steps, known isolation region for STI are obtained. In the present embodiment, concave portions are formed on the surface of the isolation insulating film 106 in the later step. Therefore, the shape of the insulating member 106ins for isolation finally obtained is different from that in the conventional case.

[FIG. 9]

A polycrystalline silicon film 107 having the conductive property to be processed into conductive spacers is deposited on the entire surface. The polycrystalline silicon film 107 having the conductive property is a polycrystalline silicon film having P doped therein, for example. The polycrystalline silicon film 107 is thin. The thickness of the polycrystalline silicon film 107 is 20 nm, for example. Therefore, the space between the adjacent floating gate electrodes 102 is not filled with the polycrystalline silicon film 107.

[FIG. 10]

By etching (etching back) the polycrystalline silicon film 107 by RIE process without using a mask, conductive spacers 107 are selectively formed on the side surfaces of the floating gate electrodes 102.

As source gas, for example, a mixed gas of HBr and O₂ or a mixed gas of Cl₂ and O₂ is used. By using the above source gas, the isolation insulating films 106 (SiO₂) are not etched and the polycrystalline silicon film 107 is selectively etched.

The conductive spacer 107 has a surface shape (domed shape) with the positive curvature and the thickness in the lateral direction which becomes larger in the downward direction. As a result, sharp corner portions are not formed on the upper portions of the floating gate electrodes 102.

Since the conductive spacers 107 are formed by etching-back of the polycrystalline silicon film, the morphology of the Si surface of the conductive spacer 107 becomes preferable (the Si surface becomes smooth). Therefore, a preferable gate interelectrode insulating film 111 (for example, an ONO film) can be easily formed on the conductive spacers 107 in the later step.

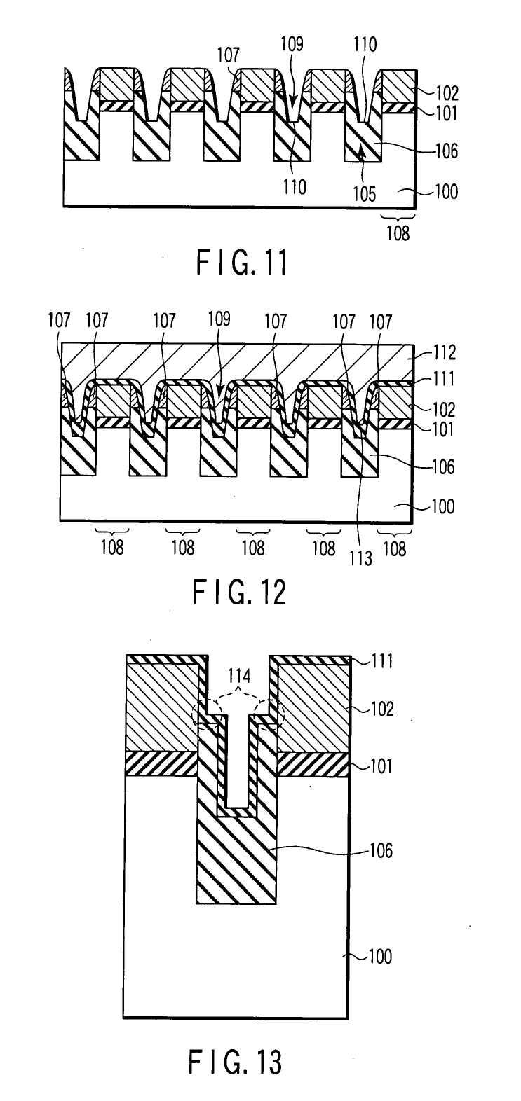

On other hand, when the conductive spacers (polycrystalline silicon film) 107 are not formed, since the floating gate electrodes 102 are formed by transferring the side surfaces of the resist pattern 104 and hard mask (silicon nitride film) 102 onto the polycrystalline silicon film by RIE process, the side surfaces of the floating gate electrodes 102 become rough and the morphology of the Si surface is deteriorated. Therefore, it becomes difficult to form a preferable gate interelectrode insulating film 111 (for example, an ONO film) on the conductive spacers 107 in the later step.

[FIG. 11]

By etching the isolation insulating films 106 by RIE process using the conductive spacers 107 as a mask, concave portions (slits) 109 are formed on the surfaces of the isolation insulating films 106 in a self-alignment manner. The concave portion 109 has inclined surfaces. That is, the concave portion 109 has a forwardly tapered shape (trapezoidal shape) whose width becomes smaller in the downward direction.

The position of a front end 110 of the concave portion 109 is set in a position lower than the bottom surface of the floating gate electrode 102 and higher than the bottom surface (the surface of the silicon substrate 100) of the trench 105 for STI. In the present embodiment, the front end 110 of the concave portion 109 is set lower than the bottom surface of the tunnel insulating film 101.

Since the concave portions 109 are formed in the self-alignment manner, no variation occurs in the shapes of the concave portions 109. The isolation insulating films 106 are subjected to dry etching so that the shape of the concave portion 109 becomes forwardly tapered. Therefore, in the step of forming the concave portions 109, the side surfaces (silicon surfaces) of the trenches 105 are not etched.

[FIG. 12]

A gate interelectrode insulating film 111 is formed on the island shaped regions 108 and conductive spacers 107 and regions between the adjacent island shaped regions 108. Since the concave portion 109 has a forwardly tapered shape, the gate interelectrode insulating film 111 is easily formed on the side surfaces of the concave portions 109.

The gate interelectrode insulating film 111 is an ONO film (oxide film-silicon nitride film-oxide film), for example. When the ONO film is used, it is preferable to set the phosphorus concentration of the conductive spacer 107 (polycrystalline silicon film or amorphous silicon film) higher than the phosphorus concentration of the floating gate electrode 102 (polycrystalline silicon film or amorphous silicon film). For example, the phosphorus concentration of the conductive spacer 107 is set to 3×10²⁰ atoms/cm³ and the phosphorus concentration of the floating gate electrode 102 is set to 2×10²⁰ atoms/cm³. When an oxide film is formed by thermally oxidizing the silicon film containing phosphorus, the growth rate of the oxide film varies depending on the phosphorus concentration. That is, the growth rate becomes higher as the phosphorus concentration becomes higher. Therefore, the thickness of a bottom oxide film on the upper edge portion of the floating gate electrode 102 and the thickness of the bottom oxide film on the side surfaces of the floating gate electrode 102 on which oxide films are difficult to be formed can be made larger in comparison with the top surface of the floating gate electrode 102 by forming a first oxide film (the bottom oxide film) of the ONO film by thermally oxidizing method. Thereby, the reliability of the gate interelectrode insulating film 111 (ONO film) can be enhanced. Moreover, as the gate interelectrode insulating film 111, a high-k insulating film such as an Al₂O₃ (alumina) film formed by ALD (Atomic Layer Deposition)-CVD process can be used. By using the high-k insulating film, the capacitance (coupling ratio (C2/(C1+C2)) between the floating gate electrode and the control gate is increased. As a result, the write voltage is lowered. C1 indicates the coupling capacitance between the FG electrode and the substrate, C2 indicates the coupling capacitance between the control gate electrode and the FG electrode.

A polycrystalline silicon film to be processed into the control gate electrode 112 is formed on the gate interelectrode insulating film 111. Each space between the adjacent island shaped regions 108 is filled with the polycrystalline silicon film. Since the concave portion 109 has the forwardly tapered shape, the polycrystalline silicon film is easily filled into the concave portion 109. The thickness of the polycrystalline silicon film is set to 150 nm, for example. The front edge (bottom surface) 113 of the control gate electrode 112 is positioned lower than the bottom surface of the floating gate electrode 102.

The polycrystalline silicon film, the gate interelectrode insulating film 111 and the floating gate electrode 102 are patterned by RIE process to form control gate electrodes 112 (word lines) and the shape of the floating gate electrode 102 in the channel length direction is determined.

Sharp corner portions do not exist on the upper portion of the floating gate electrode 102. Since the sharp corner portions do not exist, an electric field is not concentrated in the gate interelectrode insulating film 111 between the upper portions of the floating gate electrodes 102 and the control gate electrode 112. Therefore, a leak current (deterioration in the dielectric strength) flowing through the gate interelectrode insulating film 111 at the time of data write/erase operation can be suppressed.

The conductive spacers 107 are provided on the upper side surfaces of the floating gate electrodes 102. The conductive spacers 107 also function as the floating gate electrodes. Therefore, the substantial surface area of the floating gate electrode 102 is increased by the conductive spacers 107 in comparison with a case wherein only the floating gate electrode 102 is used. Thereby, the coupling ratio can be enhanced. As a result, the write voltage can be lowered.

The front edge 113 of the control gate electrode 112 is positioned lower than the bottom surface of the floating gate electrode 102. Therefore, the adjacent floating gate electrodes 102 are electrostatically shielded by the control gate electrode 112. Thus, a variation (variation in the threshold voltage) in the electric potential of the floating gate electrode 102 due to the coupling capacitance between the adjacent floating gate electrodes 102 is suppressed.

The step coverage of the gate interelectrode insulating film 111 is improved by the conductive spacers 107. If the conductive spacers 107 do not exist, the thickness of the gate interelectrode insulating film 111 becomes smaller in boundary portions 114 between the floating gate electrodes 102 and the isolation insulating film 106 as shown in FIG. 13. Alternatively, the gate interelectrode insulating film 111 will be divided in the boundary portions 114.

After the formation of the control gate electrode 112, an interlayer insulating film 115 and bit lines 116 are formed to complete the device structure shown in FIG. 3. Thereafter, a step of forming a known multi-layer interconnection is performed to attain a flash memory.

As described above, according to the present embodiment, the leak current is suppressed, the write voltage is lowered and a variation in the threshold voltage is suppressed. Thereby, even if the device element is further miniaturized, a flash memory which is highly reliable in the operation can be realized.

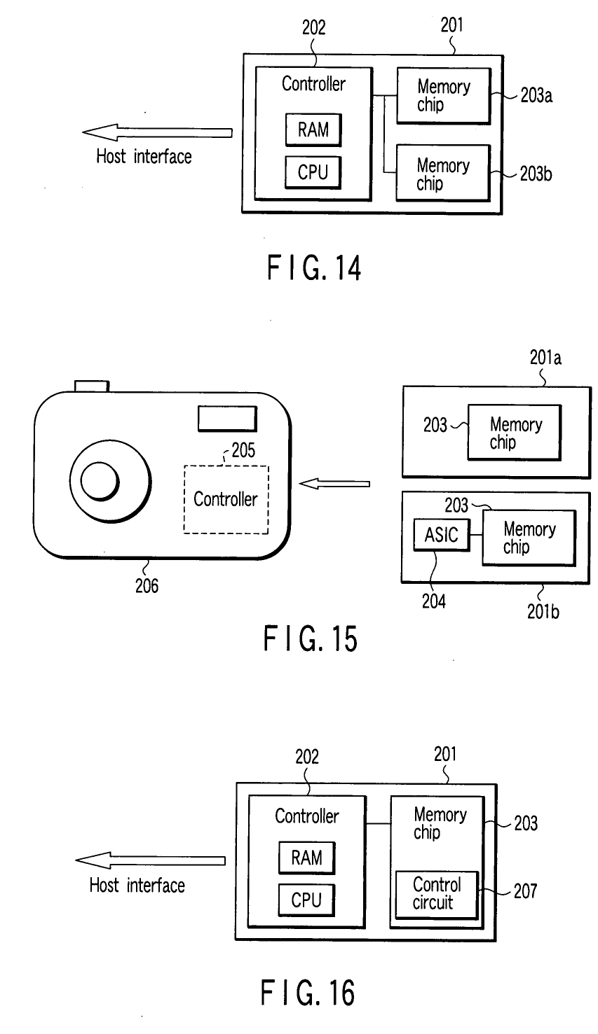

In addition, the present invention is not limited to the above embodiment. For example, the present invention can be applied to a device comprising a NAND type flash memory. Examples of the device are shown in FIGS. 14 to 16.

Concrete examples of the device comprising the NAND type flash memory of the embodiment are shown in FIGS. 14 to 16.

FIG. 14 shows a memory card comprising a controller and hybrid chip. A controller 202 and a plurality of memory chips 203a, 203b are mounted on a memory card 201. The memory chips 203a, 203b each comprise the NAND type flash memory of the present embodiment.

As a host interface, for example, an ATA interface, PC card interface, USB or the like are given. An interface other than the above interfaces can be used. The controller 202 comprises a RAM and CPU. The controller 202 and memory chips 203a, 203b may be formed on one chip or on different chips.

FIG. 15 shows a memory card having no controller mounted thereon. In this example, it is aimed to a device such as a card 201a having only a memory chip 203 mounted thereon or a card 201b having a relatively small-scale logic circuit (ASIC) 204 mounted thereon. The memory chip 203 comprises the NAND type flash memory of the present embodiment. An equipment on the host side connected to the cards 201a, 201b is a digital camera 206 having a controller 205, for example.

FIG. 16 shows a memory chip having a control circuit mounted thereon. A controller 202 and memory chip 203 are mounted on the memory card 201. The memory chip 203 comprises a control circuit 207.

In addition, the present invention can be applied to a nonvolatile semiconductor memory other than the NAND type flash memory.

In addition, the present invention can be applied to a semiconductor device using a semiconductor substrate other than the silicon substrate. As the semiconductor substrate other than the silicon substrate, for example, an SOI substrate, SiGe substrate or a silicon substrate part (for example, current path) of which is formed of SiGe can be given.

In addition, this invention can be applied to a case wherein the floating gate electrode 102 and first conductive spacers 107 are formed of different conductive materials.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a trench type isolation region provided on a surface of the semiconductor substrate; and
an electrically-rewritable nonvolatile semiconductor memory cell array including first and second memory cells isolated each other by the trench type isolation region and lying adjacently each other;
the first memory cell comprising a first island shaped region and a first conductive spacer, the first island shaped region including a first island shaped semiconductor portion provided on the semiconductor substrate, a first insulating film provided on the first semiconductor portion and a first floating gate electrode provided on the first insulating film, the first conductive spacer being selectively provided on a side surface of an upper portion of the first floating gate electrode,
the second memory cell comprising a second island shaped region and a second conductive spacer, the second island shaped region including a second island shaped semiconductor portion being adjacent to the first island shaped semiconductor portion and provided on the semiconductor substrate which is separated from the first island shaped semiconductor portion by the trench type isolation region, a second insulating film provided on the second island shaped semiconductor portion, and a second floating gate electrode provided on the second insulating film, the second conductive spacer being selectively provided on a side surface of an upper portion of the second floating gate electrode,
the first and second memory cells further comprising an interelectrode insulating film, and a control gate electrode provided on the interelectrode insulating film, the interelectrode insulating film being provided on the first island shaped region, the first conductive spacer, the second island shaped region, the second conductive spacer and an region between the first island shaped region and the second island shaped region, and a front edge of an under portion of the interelectrode insulating film being positioned lower than bottom surfaces of the first and second floating gate electrodes, a front edge of an under portion of the control gate electrode being positioned equal to the bottom surfaces of the first and second floating gate electrodes or lower,
the interelectrode insulating film being failed to have a bending portion between a side surface of the first floating gate electrode and the control gate electrode, and between a side surface of the second floating gate electrode and the control gate electrode.

2. The semiconductor device according to claim 1, wherein the trench type isolation region comprises an insulating member having a concave portion on its surface, the insulating member is provided between the first island shaped region and the second island shaped region, a bottom of the concave portion of the insulating member is positioned lower than the bottom surfaces of the first and second floating gate electrodes, and the front edge of the interelectrode insulating film and the front edge of the control gate electrode are provided in the concave portion of the insulating member.

3. The semiconductor device according to claim 2, wherein the bottom of the concave portion of the insulating member is positioned lower than bottom surfaces of the first and second insulating films, and the front edge of the control gate electrode is positioned lower than bottom surfaces of the first and second floating gate electrodes.

4. The semiconductor device according to claim 1, wherein dimensions of lateral direction of the first and second conductive spacers increase toward the bottom surface of the first and second floating gate electrodes from top surfaces of the first and second floating gate electrodes.

5. The semiconductor device according to claim 2, wherein dimensions of lateral direction of the first and second conductive spacers increase toward the bottom surface of the first and second floating gate electrodes from top surfaces of the first and second floating gate electrodes.

6. The semiconductor device according to claim 1, wherein a side surface of an upper portion of the insulating member substantially continuously connects to surfaces of under portions of the first and second conductive spacers on the side surface of the upper portion of the insulating member.

7. The semiconductor device according to claim 2, wherein a side surface of an upper portion of the insulating member substantially continuously connects to surfaces of under portions of the first and second conductive spacers on the side surface of the upper portion of the insulating member.

8. The semiconductor device according to claim 6, wherein the concave portion of the insulating member includes a side surface having shape such that width of the concave portion narrows toward the bottom.

9. The semiconductor device according to claim 7, wherein the concave portion of the insulating member includes a side surface having shape such that width of the concave portion narrows toward the bottom.

10. The semiconductor device according to claim 8, wherein the bottom of the concave portion of the insulating member locates in a central region between the first conductive spacer and the second conductive spacer viewed from top.

11. The semiconductor device according to claim 9, wherein the bottom of the concave portion of the insulating member locates in a central region between the first conductive spacer and the second conductive spacer viewed from top.

12. The semiconductor device according to claim 1, wherein the first and second floating gate electrodes includes material same as that of the first and second floating gate electrodes.

13. The semiconductor device according to claim 1, wherein the first and second insulating films are tunnel insulating films.

14. A method for manufacturing a semiconductor device comprising a semiconductor substrate, a trench type isolation region provided on a surface of the semiconductor substrate, an electrically-rewritable nonvolatile semiconductor memory cell array including first and second memory cells isolated each other by the trench type isolation region and lying adjacently each other, the method comprising:
forming the first memory cell;
forming the second memory cell;
the forming the first and second memory cells comprising:
forming an insulating film to be processed into the first and second insulating films,
forming a conductive film to be processed into the first and second floating gate electrode,
forming the first and second floating gate electrodes, forming the first and second insulating films respectively under the first and second floating gate electrodes, and forming first and second island shaped semiconductor portions respectively under the first and second insulating films by etching the conductive film, the insulating film, the semiconductor substrate,
filling a region between a first island shaped region and a second island shaped region with an insulating member, the first island shaped region including the first island shaped semiconductor portion, the first insulating film and the first floating gate electrode, the second island shaped region including the second island shaped semiconductor portion, the second insulating film and the second floating gate electrode, and a top surface of the insulating member being lower than top surfaces of the first and second of the floating gate electrodes and higher than bottom surfaces of the first and second of the floating gate electrodes
forming first and second conductive spacers respectively on side surfaces of the first and second floating gate electrodes which are not covered with the insulating member,
forming a concave portion on a surface of the insulating member by etching the insulating member using the first and second conductive spacers as a mask, a bottom of the concave portion being lower than the bottom surfaces of the first and second floating gate electrodes,
forming an interelectrode insulating film and a control gate electrode, the interelectrode insulating film being formed on the first island shaped region, the first conductive spacer, the second island shaped region, the second conductive spacer and an region between the first island shaped region and the second island shaped region, the control gate electrode being formed on the interelectrode insulating film, a front edge of the under portion of interelectrode insulating film and a front edge of the under portion of the control gate electrode being in the concave portion of the insulating member, the front edge of the under portion of the interelectrode insulating film being positioned lower than bottom surfaces of the first and second floating gate electrodes, the front edge of the under portion of the control gate electrode being positioned equal to the bottom surfaces of the first and second floating gate electrodes or lower, the interelectrode insulating film being failed to have a bending portion between a side surface of the first floating gate electrode and the control gate electrode, and between a side surface of the second floating gate electrode and the control gate electrode.

15. The method for manufacturing the semiconductor device according to claim 14, wherein the forming the first and second conductive spacers comprises forming a conductive film to be processed into the first and second conductive spacers on an entire surface, and performing anisotropic etching to an entire surface of the conductive film.

16. The method for manufacturing the semiconductor device according to claim 14, wherein the conductive film to be processed into the first and second floating gate electrodes, and the conductive film to be processed into the first and second conductive spacers are same kind of conductive films.

17. The method for manufacturing the semiconductor device according to claim 16, wherein the same kind of conductive films are polycrystalline silicon films including dopants.

18. The method for manufacturing the semiconductor device according to claim 14, wherein the forming the concave portion on the surface of the insulating member comprises etching the insulating member using the first and second conductive spacers as a mask until the bottom of the concave portion positions lower than bottom surfaces of the first and second insulating films.

19. The method for manufacturing the semiconductor device according to claim 15, wherein the forming the concave portion on the surface of the insulating member comprises etching the insulating member using the first and second conductive spacers as a mask until the bottom of the concave portion positions lower than bottom surfaces of the first and second insulating films.

20. The method for manufacturing the semiconductor device according to claim 16, wherein the forming the concave portion on the surface of the insulating member comprises etching the insulating member using the first and second conductive spacers as a mask until the bottom of the concave portion positions lower than bottom surfaces of the first and second insulating films.
